(19) United States
(12) Patent Application Publication
(10) Pub. No.: US 2025/0031559 A1
(43) Pub. Date: Jan. 23, 2025

(54) APPARATUS FOR MANUFACTURING DISPLAY DEVICE

(71) Applicant: Samsung Display Co., LTD., Yongin-si (KR)

(72) Inventors: Jong Yoon LEE, Yongin-si (KR); Sok Won NOH, Yongin-si (KR)

(73) Assignee: Samsung Display Co., LTD., Yongin-si (KR)

(21) Appl. No.: 18/774,172

(22) Filed: Jul. 16, 2024

(30) Foreign Application Priority Data
Jul. 18, 2023 (KR) 10-2023-0093392

(51) Int. Cl. H10K 71/16; C23C 14/04; C23C 14/24; C23C 14/54

(52) U.S. Cl. CPC H10K 71/164; C23C 14/042; C23C 14/243; C23C 14/54

(57) ABSTRACT

An apparatus for manufacturing a display device includes: a substrate; a nozzle including a nozzle hole that sprays a deposition material on the substrate; a crucible connected to the nozzle, the crucible storing the deposition material; a reflector disposed on the crucible, the reflector including an opening area overlapping the nozzle; and an angle control member connected to the reflector. The angle control member includes a first member disposed to face the nozzle, a third member disposed to face the substrate, and a second member disposed between the first member and the third member.

### CROSS-REFERENCE TO RELATED APPLICATION(S)

This application claims priority to and benefits of Korean patent application No. 10-2023-0093392 under 35 U.S.C. § 119, filed on Jul. 18, 2023, in the Korean Intellectual Property Office, the entire contents of which are incorporated herein by reference.

### BACKGROUND

### 1. Technical Field

Embodiments relate to an apparatus for manufacturing a display device.

### 2. Description of the Related Art

Recently, as interest in information displays is increased, research and development of display devices have been continuously conducted.

### SUMMARY

Embodiments provide a manufacturing apparatus for depositing an organic material on a substrate of a display device.

However, embodiments of the disclosure are not limited to those set forth herein. The above and other embodiments will become more apparent to one of ordinary skill in the art to which the disclosure pertains by referencing the detailed description of the disclosure given below.

In accordance with an aspect of the disclosure, an apparatus for manufacturing a display device may include: a substrate; a nozzle including a nozzle hole that sprays a deposition material on the substrate; a crucible connected to the nozzle, the crucible storing the deposition material; a reflector disposed on the crucible, the reflector including an opening area overlapping the nozzle; and an angle control member connected to the reflector. The angle control member may include a first member disposed to face the nozzle, a third member disposed to face the substrate, and a second member disposed between the first member and the third member.

The second member may include a heater that includes a heat wire and applies heat to the first member.

The first member may include a heat dissipation member having a high emissivity.

The third member may include a plurality of heat dissipation members each having a low emissivity.

Each of the heat dissipation members may be mirror-finished to reflect radiant heat transmitted from the heater.

The angle control member may have an inclination angle of about 40° to about 70°.

The angle control member may include a first angle control member and a second angle control member, which are spaced apart from each other.

The first angle control member may have a first inclination angle of about 40° to about 70°, and the second angle control member may have a second inclination angle of about 40° to about 70°.

The first inclination angle and the second inclination angle may be same as each other.

The first inclination angle and the second inclination angle may be different from each other.

Each of the first and second angle control members may include a first part connected to the reflector and a second part extending from the first part toward the substrate. The second part may have an inclination angle of about 40° to about 70°.

Each of the first and second angle control members may include a curve having a curvature.

An angle formed by a tangent line in contact with an arbitrary point of the curve and a virtual line parallel to a main surface of the reflector may be in a range of about 40° to about 70°.

Each of the first and second angle control members may include a first part connected to the reflector and a second part extending from the first part toward the nozzle. An angle formed by the first part and the second part may be in a range of about 40° to about 70°.

The apparatus may further include a heater heating the crucible and disposed at an outer periphery of the crucible.

In accordance with another aspect of the disclosure, there is provided an apparatus for manufacturing a display device, the apparatus including: a crucible including an accommodation part storing a deposition material to be deposited on a substrate; a heater disposed at an outside of the crucible, the heater that heats the crucible and evaporates the deposition material; a nozzle communicating with the accommodation part, the nozzle including a nozzle hole that sprays the deposition material toward the substrate; a reflector disposed between the crucible and the nozzle, the reflector that blocks heat exchange between the crucible and the nozzle; and an angle control member connected to the reflector. The angle control member may include a first member, a second member, and a third member. The second member may include a heat wire and applies heat to the first member.

The angle control member may have an inclination angle of about 40° to about 70°.

The first member may face the nozzle, the third member may face the substrate, and the second member may be disposed between the first member and the third member.

The first member may include a heat dissipation member having a high emissivity, and the third member may include a plurality of heat dissipation members each having a low emissivity.

Each of the heat dissipation members may be mirror-finished to reflect heat transmitted from the second member.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a schematic view illustrating an apparatus for manufacturing a display device in accordance with an embodiment.

FIG. 2 is a schematic view illustrating a method in which a deposition source shown in FIG. 1 moves.

FIG. 3 is a schematic perspective view illustrating the deposition source shown in FIG. 2.

FIG. 4 is a schematic plan view illustrating the deposition source shown in FIG. 3.

FIG. 5 is a schematic sectional view taken along line I-I′ shown in FIG. 4.

FIGS. 6A, 6B, and 6C are enlarged schematic views illustrating portion EA shown in FIG. 5.

FIG. 7 is a schematic view illustrating a second member shown in FIG. 6A.

FIGS. 8, 9, and 10 illustrate various embodiments of an angle control member shown in FIG. 5, and are enlarged schematic views corresponding to the portion EA shown in FIG. 5.

FIG. 11 is a schematic plan view illustrating a display device manufactured by using the apparatus in accordance with an embodiment.

FIG. 12 is a schematic sectional view illustrating a display panel shown in FIG. 11.

FIG. 13 is a schematic sectional view illustrating a pixel shown in FIG. 11.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element (or a layer) is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the X, Y, and Z-axes, and may be interpreted in a broader sense. For example, the DR1-axis, the DR2-axis, and the DR3-axis may be perpendicular to one another, or may represent different directions that are not perpendicular to one another. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein are interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

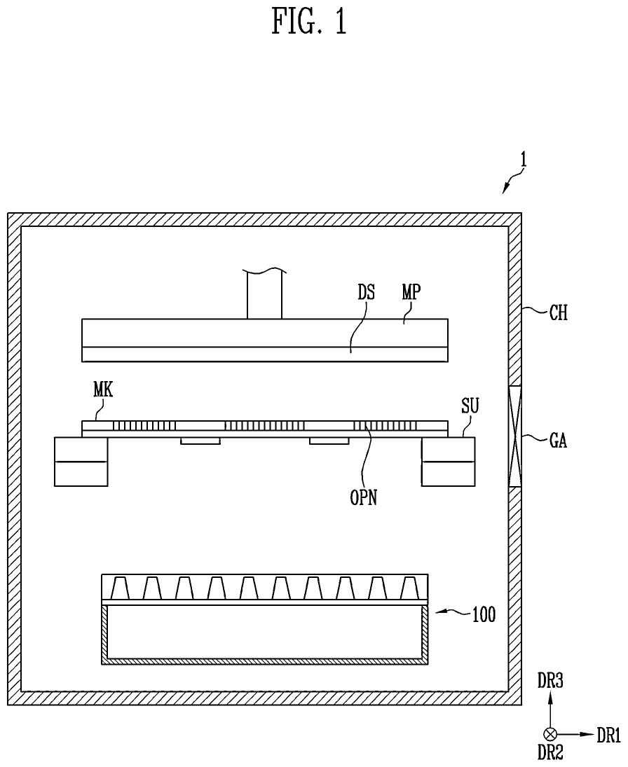

FIG. 1 is a schematic view illustrating an apparatus 1 for manufacturing a display device in accordance with an embodiment.

Referring to FIG. 1, a deposition apparatus 1 may deposit a deposition material on a target substrate DS. For example, the target substrate DS may be a substrate of a display device. The deposition material may include an organic material. The deposition material may be deposited on the target substrate DS to form a light emitting element including an organic light emitting diode.

The deposition apparatus 1 may include a chamber CH, a moving plate MP, a mask assembly MK, and a deposition source 100.

The chamber CH may have a space (or enclosed space) thereinside. The inside of the chamber CH may be maintained in a reduced-pressure (or low-pressure) atmosphere. The moving plate MP, the mask assembly MK, and the deposition source 100 may be disposed in the space inside the chamber CH. The chamber CH may have at least one gate GA. For example, the gate GA may be disposed at a side surface of the chamber CH. The gate GA may open or close the chamber CH. For example, the target substrate DS may enter in (or go out) of the chamber CH through the gate GA.

The moving plate MP may move in the chamber CH. For example, the moving plate MP may move in a first direction DR1, a second direction DR2, and a third direction DR3 in a state in which an upper portion of the moving plate MP is connected to a ceiling. In FIG. 1, each of the first direction DR1 and the second direction DR2 intersecting the first direction DR1 is defined as a substantially horizontal direction, and the third direction DR3 is defined as a vertical direction.

The mask assembly MK may be disposed between the target substrate DS and the deposition source 100. The mask assembly MK may overlap the target substrate DS. The mask assembly MK may be supported by a support part SU disposed inside the chamber CH. The support part SU may include an electrostatic chuck, a vacuum chuck or an adhesive chuck, which fixes the mask assembly MK. For example, the support part SU may include a shuttle which linearly moves the mask assembly MK in a direction by fixing the mask assembly MK, and the like.

Openings OPN may be defined in the mask assembly MK. Deposition materials transmitted in the deposition apparatus 1 may be deposited on the target substrate DS with passing through the openings OPN.

The deposition source 100 may be disposed under the mask assembly MK. The deposition source 100 may accommodate (or store) a deposition material therein. The deposition source 100 may evaporate or sublime the deposition material stored in the deposition source 100, and may provide the evaporated or sublimed deposition material to the target substrate DS.

A cooling member for suppressing (or preventing) a temperature increase of the target substrate DS may be positioned inside the chamber CH. An alignment device for aligning at least one sides of the target substrate DS and the mask assembly MK may be disposed inside the chamber CH.

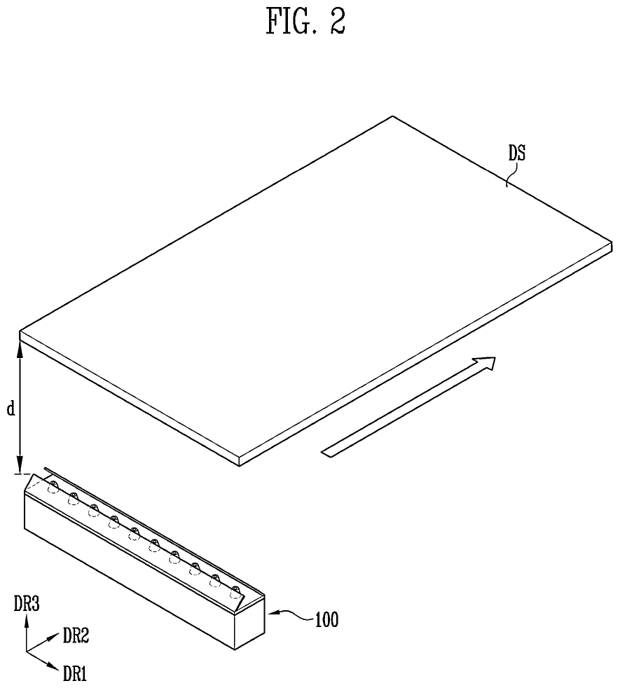

FIG. 2 is a schematic view illustrating a method in which the deposition source 100 shown in FIG. 1 moves. For convenience of description, the target substrate DS and the deposition source 100, which are shown in FIG. 1, are illustrated in FIG. 2, and illustration of the other components is omitted.

Referring to FIGS. 1 and 2, the target substrate DS may be above the deposition source 100. A surface of the target substrate DS may face the deposition source 100. The target substrate DS may include two sides extending in the first direction DR1 and two sides extending in the second direction DR2.

When viewed on a plane, the target substrate DS may have a quadrangular shape, but embodiments are not limited thereto. In an embodiment, “when viewed on a plane” or “in plan view” may mean when viewed in the third direction.

The deposition source 100 may be spaced apart from the target substrate DS. For example, the deposition source 100 may be spaced apart from the target substrate DS by a distance d in the third direction DR3. The deposition source 100 may extend in the first direction DR1. The deposition source 100 may move in the second direction DR2.

In a state in which the target substrate DS is fixed, the deposition source 100 may provide a deposition material on the surface of the target substrate DS with moving in the second direction DR2. However, embodiments are not limited thereto. In some embodiments, in a state in which the deposition source 100 is fixed, the deposition source 100 may deposit a deposition material on the surface of the target substrate DS while the target substrate DS is moved in the second direction DR2. The target substrate DS may be moved by the moving plate MP shown in FIG. 1.

Hereinafter, a structure of the deposition source 100 will be described in detail.

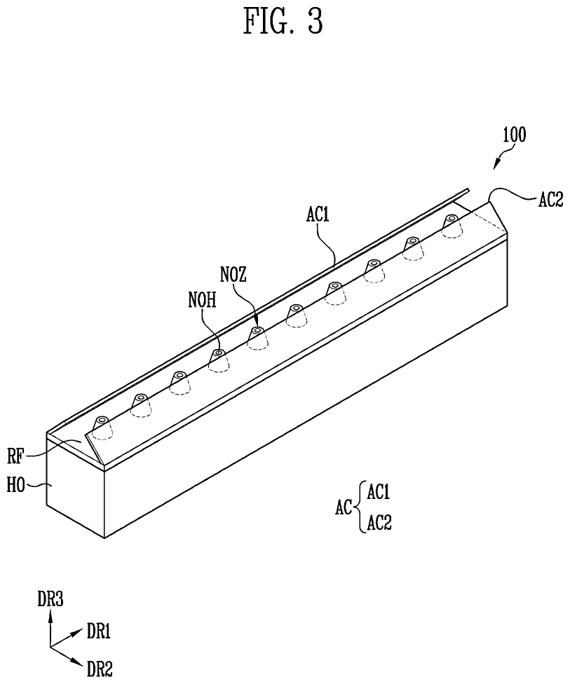

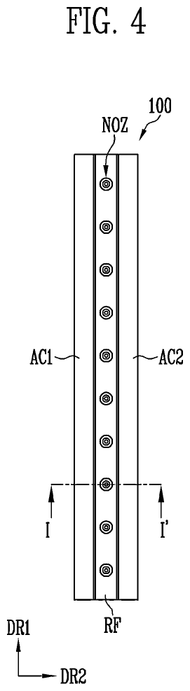

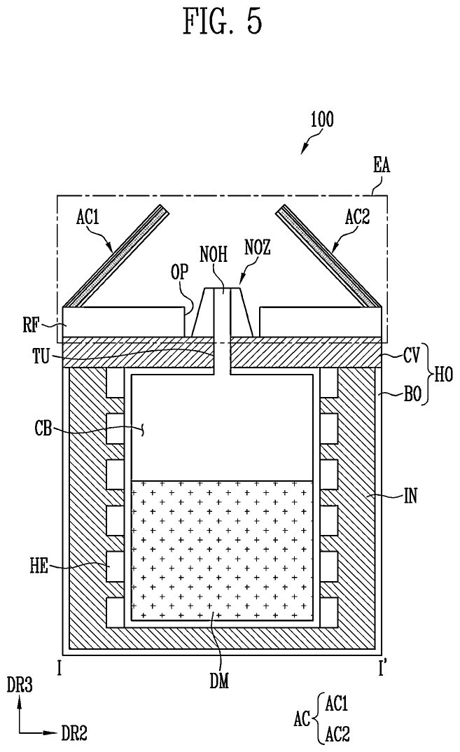

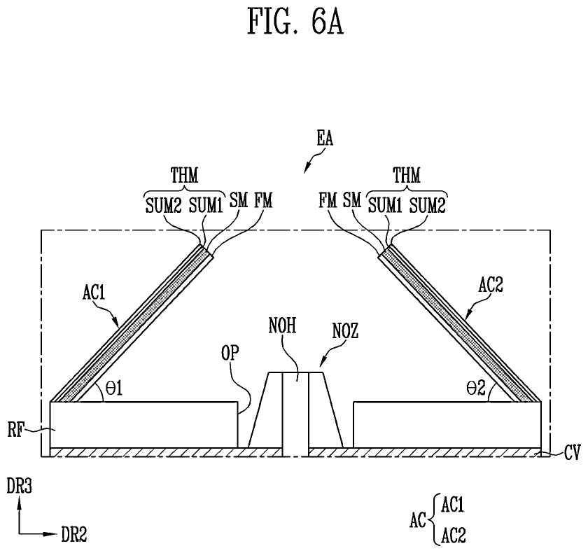

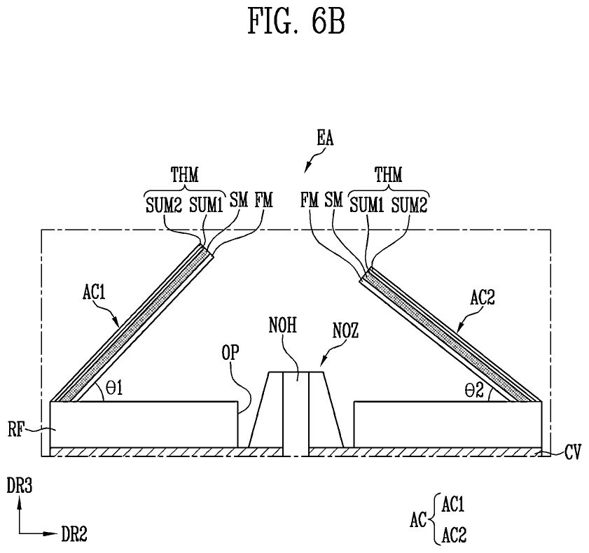

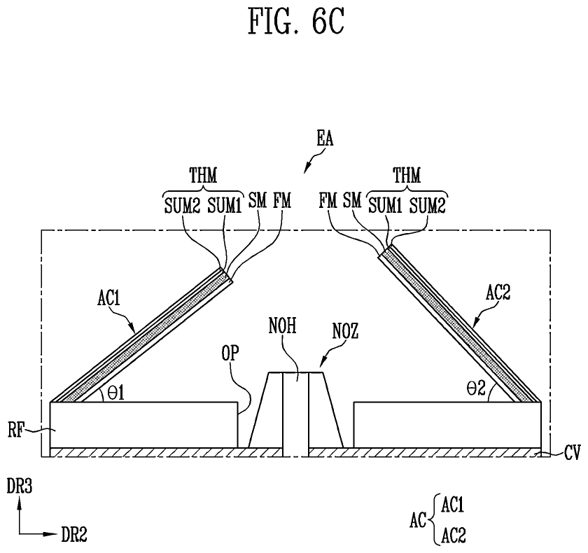

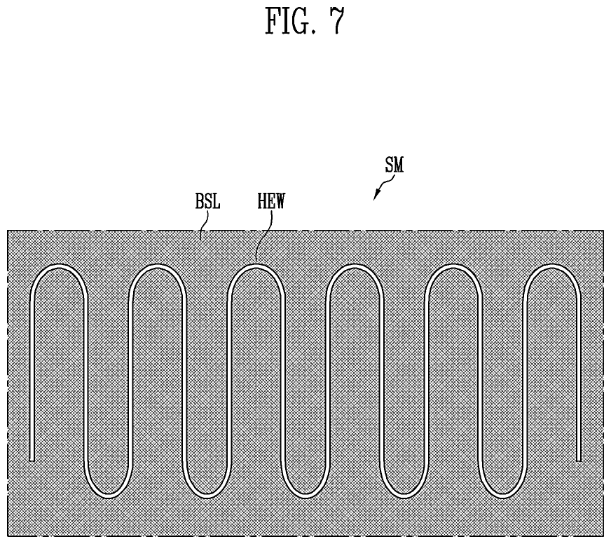

FIG. 3 is a schematic perspective view illustrating the deposition source 100 shown in FIG. 2. FIG. 4 is a schematic plan view illustrating the deposition source 100 shown in FIG. 3. FIG. 5 is a schematic sectional view taken along line I-I′ shown in FIG. 4. FIGS. 6A, 6B, and 6C are enlarged schematic views illustrating portion EA shown in FIG. 5. FIG. 7 is a schematic view illustrating a second member shown in FIG. 6A.

Referring to FIGS. 1, 2, 3, 4, 5, 6, and 7, the deposition source 100 may include a housing HO, nozzles NOZ, a crucible CB, and an angle control member AC. The housing HO may include a body BO and a cover CV.

The body BO may have an empty space thereinside. The crucible CB may be disposed inside the body BO. The cover CV may be coupled to the body BO. In another example, the cover CV may be separated from the body BO.

The nozzles NOZ may spray a deposition material into the chamber CH. The nozzles NOZ may be disposed on the housing HO. For example, the nozzles may be disposed on the cover CV of the housing HO. The nozzles NOZ may be manufactured separately from the housing HO to be coupled to the cover CV. However, embodiments are not limited thereto. In some embodiments, the nozzles NOZ may be integral with the cover CV.

The nozzles NOZ may be arranged along the first direction DR1. Nozzles NOZ adjacent to each other in the first direction DR1 may be spaced apart from each other. In FIGS. 3 and 4, it is illustrated that ten nozzles NOZ are disposed on the housing HO. However, the number of nozzles NOZ is not limited thereto.

A nozzle hole NOH may be defined in each of the nozzles NOZ. The nozzle hole NOH may have a circular shape. However, embodiments are not limited thereto, and the nozzle hole NOH may be modified to various shape including a polygonal shape, an elliptical shape, and the like.

The crucible CB may be disposed inside the housing HO. The crucible CB may have a shape corresponding to a shape of the body BO. The crucible CB may include an interior space in which a deposition material DM is stored or accommodated. The crucible CB may be a component having a length perpendicular to the movement direction of the target substrate DS, and may be variously modified. The crucible CB may be made of a heat resistant material, such as a carbon material, tantalum, or an alloy material thereof, by considering that high heat is applied to the crucible CB, but embodiments are not limited thereto. In some embodiments, the crucible CB may include a high melting point metal such as tungsten, rhenium, molybdenum, niobium, vanadium, hafnium, zirconium or titanium, or an alloy including the metal.

A connection part TU may be positioned between the crucible CB and the nozzle NOZ. The connection part TU may have a tubular shape in which a hollow (or hole) is formed, but embodiments are not limited thereto. The connection part TU may penetrate (or connect) an opening of the crucible CB and the nozzle hole NOH of the nozzle NOZ. The deposition material DM may be discharged out of the nozzle NOZ through a flow path defined by the crucible CB, the connection part TU, and the nozzle hole NOH.

The deposition source 100 may include a heater HE, a heat insulation wall IN, and a reflector RF.

The heater HE may be disposed between an inner wall of the housing HO and the crucible CB. The heater HE may apply heat to the crucible CB. The deposition material DM stored in the crucible CB may be evaporated or sublimed by a heat (or radiant heat) transferred from the heater HE. The heater HE may be disposed on a side surface of the crucible CB, but embodiments are not limited thereto. In some embodiments, the heater HE may be disposed on the bottom of the crucible CB.

The heater HE may be supplied with electric energy from the outside to convert the electric energy into thermal energy. The thermal energy transmitted from the heater HE may heat the crucible CB, thereby evaporating the deposition material DM. For example, the heater HE may heat the deposition material DM stored in the crucible CB and discharge steam of the deposition material DM through the opening of the crucible CB. The heater HE may include, for example, a sheath heating unit/part or a resistance heating type heating unit/part such as a metal wire line. However, embodiments are not limited thereto, and various heating methods of evaporating the deposition material DM may be implemented. The heater HE may have various shapes including a plate shape, a wire shape, a mesh shape, and the like.

The heat insulating wall IN may surround the crucible CB. The heat insulation wall IN may prevent heat inside the housing HO from being leaked to the outside. Accordingly, influence on the target substrate DS, which is caused by heat generated in the deposition source 100, may be minimized or prevented.

The reflector RF may be disposed on the top of the cover CV to expose the nozzles NOZ, and may be coupled to the housing HO. For example, the reflector RF may include an opening area OP corresponding to the nozzles NOZ. The reflector RF may extend along the first direction DR1, and may be formed as a plate penetrated by the nozzles NOZ. The reflector RF may include a heat insulation material. The reflector RF may prevent heat of the crucible CB from being leaked in an upper direction of the housing HO. Accordingly, the reflector RF may block heat leaked toward the target substrate DS disposed above the deposition source 100.

The angle control member AC may control a deposition area of the deposition material DM sprayed toward the target substrate DS through the nozzle NOZ. For example, the angle control member AC may control the deposition area of the deposition material DM with respect to the second direction DR2 in case that the crucible CB or the target substrate DS is moved along the second direction DR2 in a process of depositing the deposition material DM on the target substrate DS. An emission angle of the deposition material DM discharged from the crucible CB may be controlled to be a certain angle or less than the certain angle. Accordingly, an incident angle of the deposition material DM onto the target substrate DS may be controlled to be the certain angle or less than the certain angle in case that deposition is performed in the apparatus 1. Thus, the patterning accuracy of a film formed through the mask assembly MK may be improved by limiting/controlling the incident angle of the deposition material DM. The deposition material DM may be prevented from being stuck to a portion, which is not included in the target substrate DS and the mask assembly MK, such as a wall surface of the chamber CH.

The angle control member AC may include a first angle control member AC1 and a second angle control member AC2, which face each other with the nozzles NOZ interposed therebetween in the second direction DR2 on the cover CV, and extend along the first direction DR1. The angle control member AC may be coupled to the reflector RE. For example, the first angle control member AC1 may be coupled to a side of the reflector RF, and the second angle control member AC2 may be coupled to another side of the reflector RE.

In an embodiment, each of the first and second angle control members AC1 and AC2 may include a first member FM, a second member SM, and a third member THM.

In each of the first and second angle control members AC1 and AC2, the first member FM may be disposed at a surface toward the reflector RF or the nozzles NOZ. The first member FM may be coupled to the reflector RF to control the deposition area of the deposition material DM.

The first member FM may be formed in a plate shape. The first member FM may include a heat dissipation coating layer having a high emissivity, thereby improving the emissivity of heat (or radiant heat) generated in the second member SM. For example, the first member FM may be formed as a heat dissipation member on which a heat dissipation coating agent including an infrared emitter powder and a binder is coated, but embodiments are not limited thereto. In some embodiments, the first member FM may further include a protective layer for protecting and smoothing a surface on which the heat dissipation coating agent is coated. The protective layer may include at least one of silane, an organic resin, a silicon compound, an inorganic binder, an organic/inorganic hybrid binder, and a glass frit, but embodiments are not limited thereto.

A first member FM of the first angle control member AC1 may be inclined with respect to a direction, e.g., the third direction DR3, perpendicular to a main surface of the reflector RE. An inclination angle θ1 (hereinafter, referred to as a “first inclination angle”) of the first member FM with respect to the main surface (e.g., an upper surface parallel to the second direction DR2) of the reflector RF may be in a range of about 40° to about 70°. A first member FM of the second angle control member AC2 may be inclined with respect to a direction, e.g., the third direction DR3, perpendicular to the main surface of the reflector RE. An inclination angle θ2 (hereinafter, referred to as a “second inclination angle”) of the first member FM with respect to the main surface of the reflector RF may be in a range of about 40° to about 70°.

The first inclination angle θ1 and the second inclination angle θ2 may be an angle, which is set to minimize the heat dissipation caused by the heat transferred from the opening area OP of the reflector RF to the target substrate DS (or the mask assembly MK). The first inclination angle θ1 and the second inclination angle θ2 may be substantially equal to or different from each other. For example, the first inclination angle θ1 and the second inclination angle θ2 may be substantially the same as each other and may have a range of about 40° to about 70° as shown in FIG. 6A. In some embodiments, the first inclination angle θ1 and the second inclination angle θ2 may be different from each other and may have the range of about 40° to about 70°. For example, as shown in FIG. 6B, the first inclination angle θ1 may be greater than the second inclination angle θ2. As shown in FIG. 6C, the second inclination angle θ2 may be greater than the first inclination angle θ1.

In each of the first and second angle control members AC1 and AC2, the second member SM may be disposed on the first member FM. The second member SM may have a shape corresponding to a shape of the first member FM. For example, the second member SM and the first member FM may have the same inclination angle to be inclined with respect to the third direction DR3. The second member SM may apply heat to the first member FM. The second member SM may be formed in a form in which a heat wire HEW (see FIG. 7) is inserted in a base layer BSL (see FIG. 7), but embodiments are not limited thereto. The base layer BSL may be formed in a plate shape, and may be made of at least one of boron, nitride, aluminum oxide, tantalum, and graphite, but embodiments are not limited thereto.

The second member SM may apply heat to the first member FM, by using the heat wire HEW. Accordingly, a surface temperature of the first member FM may be increased by heat (or radiant heat) transferred from the second member SM, and the first member FL may have a high emissivity to uniformly distribute the heat. The deposition material DM sprayed through the nozzle hole NOH of each nozzle NOZ to transmit upwardly therefrom may be in contact with the first member FM of each of the first and second angle control members AC1 and AC2. As the surface temperature of the first member FM is high, the deposition material DM may not be stacked on the first member FM and may be sublimed (or evaporated), although the deposition material DM is in contact with the first member FM, to transmit toward the target substrate DS through a separation space between the first angle control member AC1 and the second angle control member AC2.

In an apparatus (or a deposition apparatus) for manufacturing a display device including an existing angle control member not including the above-described first and second members FM and SM, in case that a deposition material sprayed through a nozzle hole to transmit upwardly therefrom is in contact with the angle control member, a phase change of the deposition material occurs due to a low surface temperature of the angle control member, and the phase of the deposition material is changed from a gaseous phase to a solid phase. Hence, the deposition material may be deposited on the angle control member. Accordingly, the deposition material may be wasted.

In the above-described embodiment, the first member FM and the second member SM may be provided, thereby increasing the surface temperature of the first member FM, so that the deposition material DM may be prevented to be deposited on the first member FM. Thus, the utilization rate of the deposition material DM and the deposition efficiency of the deposition source 100 may be improved without waste of the deposition material DM.

In each of the first and second angle control members AC1 and AC2, the third member THM may be disposed on the second member SM. The second member SM may be disposed between the first member FM and the third member THM. In each of the first and second angle control members AC1 and AC2, the third member THM may be disposed at a surface facing the target substrate DS (or the mask assembly MK). The third member THM and the first member FM may have the same inclination angle to be inclined with respect to the third direction DR3.

The third member THM may be formed as a double layer including a first sub-member SUM1 and a second sub-member SUM2, which are sequentially stacked.

The first sub-member SUM1 and the second sub-member SUM2 may include a material for blocking radiant heat generated in the second member SM from being transferred in an upper direction thereof, e.g., to the target substrate DS and the mask assembly MK. For example, each of the first and second sub-members SUM1 and SUM2 may be formed as a heat dissipation member including a material having a low emissivity, e.g., 0.1 or less. As the emissivity of the first and second sub-members SUM1 and SUM2 is lowered, heat conduction (or thermal conductivity) caused by radiation may be reduced, and the amount of radiant heat, which is transmitted to the target substrate DS and the mask assembly MK, may be decreased. The first and second sub-members SUM1 and SUM2 may include a material having a low thermal conductivity, e.g., 10 W/m·k or less.

The first and second sub-members SUM1 and SUM2 may include a metal having a low emissivity as well as having a low thermal conductivity, such as tantalum, molybdenum, tungsten, nickel, cobalt or stainless steel. For example, the first and second sub-members SUM1 and SUM2 may include Al₂O₃, Boron Nitride (BN), Pyrolytic Boron Nitride (PBN), which is formed by Chemical Vapor Deposition (CVD), an inorganic material such as SiO₂, an inorganic fibrous insulation, or the like. In an embodiment, in order to lower the emissivity of the first and second sub-members SUM1 and SUM2, each of the first and second sub-members SUM1 and SUM2 may be mirror-finished such that the roughness of a surface thereof may be reduced. The mirror-finished first and second sub-members SUM1 and SUM2 may reflect radiant heat transferred from the second member SM in a lower direction thereof, so that the radiant heat may be blocked from transmitting toward the target substrate DS and the mask assembly MK, which are positioned above the angle control member AC.

As described above, in each of the first and second angle control members AC1 and AC2, the third member THM including the first and second sub-members SUM1 and SUM2 may be disposed on the second member SM, so that the amount of radiant heat generated in the second member SM may be decreased, thereby preventing the radiant heat from advancing toward the mask assembly MK and the target substrate DS, which are positioned thereabove. Accordingly, the failure rate of a display device is reduced by preventing deformation of the mask assembly MK and the target substrate DS, so that the productivity of the display device may be improved.

In the above-described embodiment, it has been described that the third member THM of each of the first and second angle control members AC1 and AC2 is formed as the double layer including the first sub-member SUM1 and the second sub-member SUM2. However, embodiments are not limited thereto. The third member THM may be formed in the form of a multi-layer including heat dissipation members having a low emissivity.

As described above, each of the first and second angle control members AC1 and AC2, which includes the first member FM, the second member SM, and the third member THM, may have a shape corresponding to the shape of the first member FM. For example, each of the first and second angle control members AC1 and AC2 may have an inclination angle of about 40° to about 70° with respect to the main surface of the reflector RE.

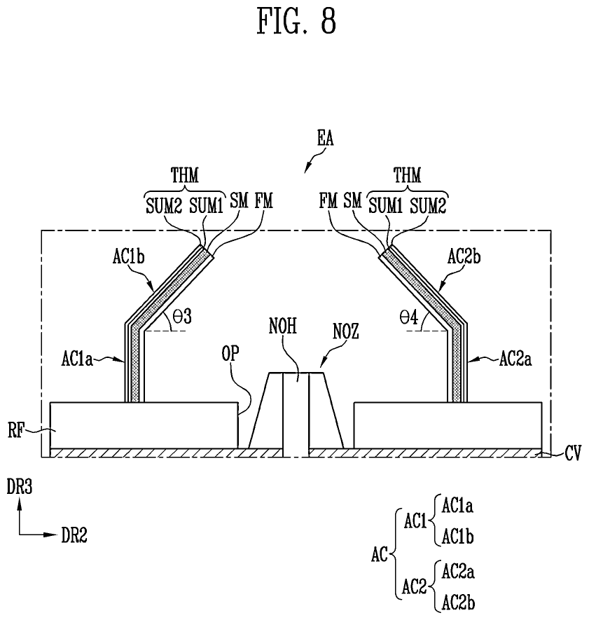

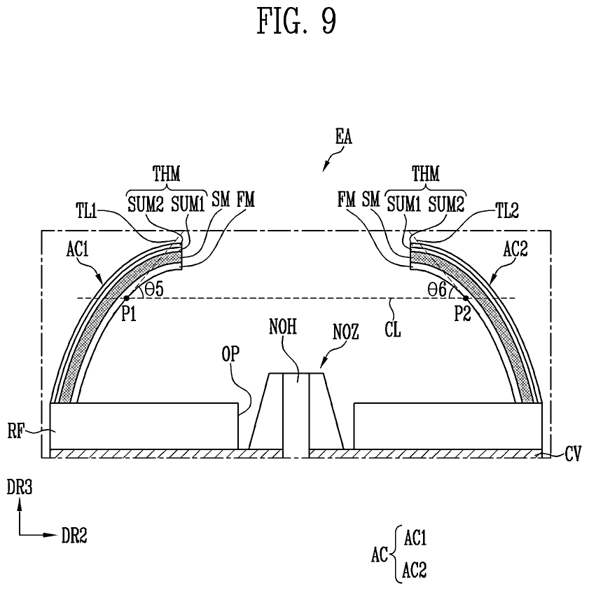

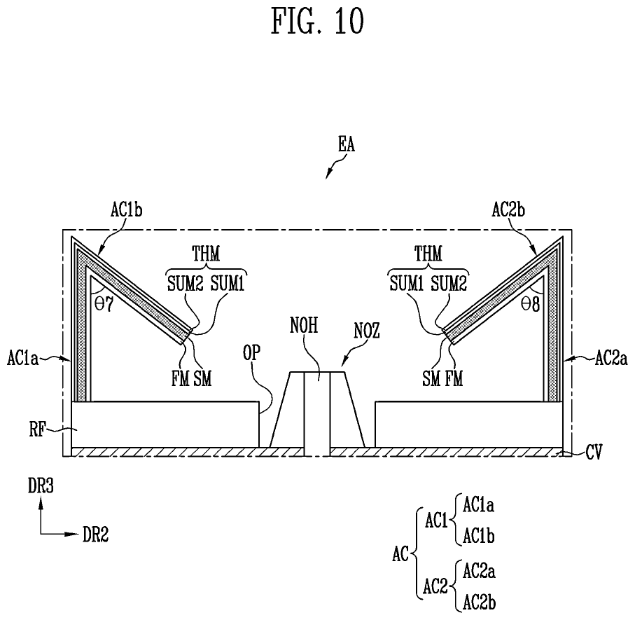

FIGS. 8, 9, and 10 illustrate various embodiments of the angle control member AC shown in FIG. 5, and are enlarged schematic views corresponding to the portion EA shown in FIG. 5.

FIGS. 8, 9, and 10 illustrate modifications of FIG. 6A in relation to the shape and the like of the angle control member AC.

In relation to the embodiments shown in FIGS. 8, 9, and 10, portions different from those of the above-described embodiment will be described to avoid redundancy.

Referring to FIGS. 1, 2, 3, 4, 5, and 8, each of first and second angle control members AC1 and AC2 may include a first part and a second part. For example, the first angle control member AC1 may include a (1-1)th part (or first part) AC1a and a (2-1)th part (or second part) AC1b, and the second angle control member AC2 may include a (1-2)th part (or first part) AC2a and a (2-2)th part (or second part) AC2b.

The (1-1)th part AC1a may be connected (or coupled) to a surface of the reflector RF, and extend along a direction, e.g., the third direction DR3, perpendicular to the main surface of the reflector RF. The (2-1)th part AC1b may extend toward the target substrate DS (or the mask assembly MK) from the (1-1)th part AC1a. The (2-1)th part AC1b may extend in a direction different from the extending direction of the (1-1)th part AC1a. For example, the (2-1)th part AC1b may extend to be inclined at a certain angle in a direction toward the nozzle NOZ from the (1-1)th part AC1a. In an embodiment, an inclination angle θ3 (hereinafter, referred to as a “third inclination angle”) of the (2-1)th part AC1b may be in a range of about 40° to about 70°.

The (1-2)th part AC2a may be connected (or coupled) to another surface of the reflector RF, and extend in the direction, e.g., the third direction DR3, perpendicular to the main surface of the reflector RF. The (2-2)th part AC2b may extend toward the target substrate DS from the (1-2)th part AC2a. The (2-2)th part AC2b may extend in a direction different from the extending direction of the (1-2)th part AC2a. For example, the (2-2)th part AC2b may extend to be inclined at a certain angle in a direction toward the nozzle NOZ from the (1-2)th part AC2a. In an embodiment, an inclination angle θ4 (hereinafter, referred to as a “fourth inclination angle”) of the (2-2)th part AC2b may be in a range of about 40° to about 70°.

The third inclination angle θ3 and the fourth inclination angle θ4 may be substantially equal to or different from each other within a range of about 40° to about 70°.

The (1-1)th part AC1a and the (1-2)th part AC2a may face each other and may be spaced apart from each other with the nozzle NOZ interposed therebetween. A first member FM of each of the (1-1)th part AC1a and the (1-2)th part AC2a may face the reflector RF or the nozzle NOZ. A third member THM of each of the (1-1)th part AC1a and the (1-2)th part AC2a may be disposed at an outermost portion. A second member SM of each of the (1-1)th part AC1a and the (1-2)th part AC2a may be disposed between the first member FM and the third member THM.

The (2-1)th part AC1b and the (2-2)th part AC2b may be spaced apart from each other. A first member FM of each of the (2-1)th part AC1b and the (2-2)th part AC2b may face the reflector RF or the nozzle NOZ. A third member THM of each of the (2-1)th part AC1b and the (2-2)th part AC2b may face the target substrate DS. A second member SM of each of the (2-1)th part AC1b and the (2-2)th part AC2b may be disposed between the first member FM and the third member THM.

Referring to FIGS. 1, 2, 3, 4, 5, and 9, each of first and second angle control members AC1 and AC2 may be formed with a curved surface rounded toward the target substrate DS from the reflector RF. For example, each of the first and second angle control members AC1 and AC2 may include a curve having a certain curvature. An inclination angle θ5 (hereinafter, referred to as a “fifth inclination angle”) formed by a first tangent line TL1 in contact with an arbitrary point P1 of a curve of the first angle control member AC1 and a virtual line CL parallel to the main surface of the reflector RF may be in a range of about 40° to about 70°. An inclination angle θ6 (hereinafter, referred to as a “sixth inclination angle”) formed by a second tangent line TL2 in contact with an arbitrary point P2 of a curve of the second angle control member AC2 and the virtual line CL may be in a range of about 40° to about 70°. The fifth inclination angle θ5 and the sixth inclination angle θ6 may be substantially equal to or different from each other within a range of about 40° to about 70°.

Referring to FIGS. 1, 2, 3, 4, 5, and 10, a first angle control member AC1 may include a (1-1)th part AC1a and a (2-1)th part AC1b, and a second angle control member AC2 may include (1-2)th part AC2a and a (2-2)th part AC2b.

The (1-1)th part AC1a may be connected to the reflector RF, and may extend in the third direction DR3 (or the direction perpendicular to the main surface of the reflector RF). The (2-1)th part AC1b may be connected to the (1-1)th part AC1a, and extend to be inclined at a certain angle in a direction toward the nozzle NOZ (or the reflector RF) from the (1-1)th part AC1a. In an embodiment, an inclination angle θ7 (hereinafter, referred to as a “seventh inclination angle”) of the (2-1)th part AC1b with respect to the (1-1)th part AC1a may be in a range of about 40° to about 70°. The (2-1)th part AC1b may be positioned more adjacent to the nozzle NOZ than the (1-1)th part AC1a in the second direction DR2.

The (1-2)th part AC2a may be connected to the reflector RF, and extend in the third direction DR3 (or the direction perpendicular to the main surface of the reflector RF). The (2-2)th part AC2b may be connected to the (1-2)th part AC2a, and may extend to be inclined at a certain angle in a direction toward the nozzle NOZ (or the reflector RF) from the (1-2)th part AC2a. In an embodiment, an inclination angle θ8 (hereinafter, referred to as an “eighth inclination angle”) of the (2-2)th part AC2b with respect to the (1-2)th part AC2a may be in a range of about 40° to about 70°. The (2-2)th part AC2b may be positioned more adjacent to the nozzle NOZ than the (1-2)th part AC2a in the second direction DR2.

The seventh inclination angle θ7 and the eighth inclination angle θ8 may be substantially equal to or different from each other within a range of about 40° to about 70°.

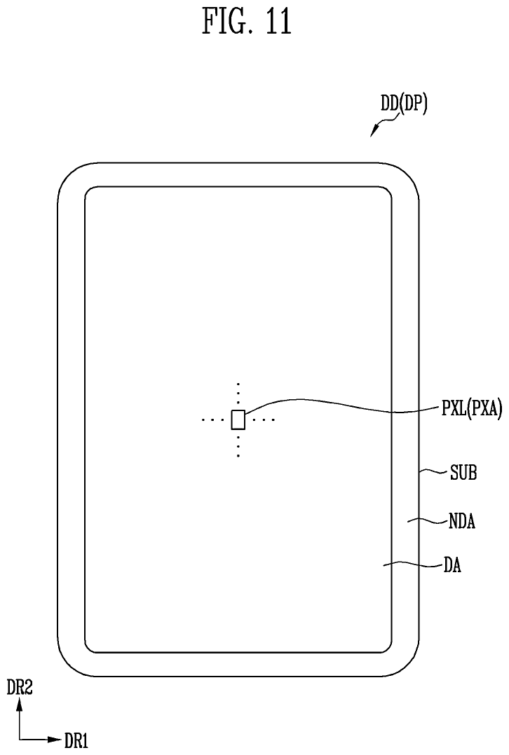

FIG. 11 is a schematic plan view illustrating a display device DD manufactured by using the apparatus in accordance with an embodiment.

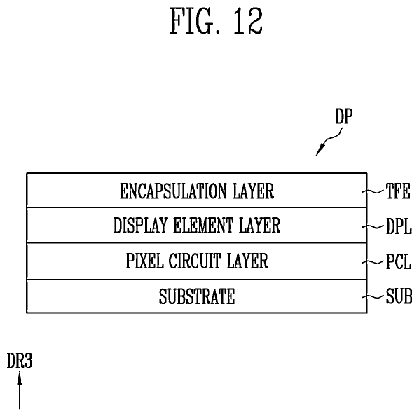

FIG. 12 is a schematic sectional view illustrating a display panel DP shown in FIG. 11.

In FIGS. 11 and 12, for descriptive convenience, a structure of the display panel DP of the display device DD is briefly illustrated based on a display area DA in which an image is displayed.

Referring to FIGS. 11 and 12, the display panel DP (or the display device DD) in accordance with the embodiment may be formed in various shapes. For example, the display panel DP may be formed in a rectangular plate shape having two pairs of sides parallel to each other, but embodiments are not limited thereto. In case that the display panel DP is formed in the rectangular plate shape, any one pair of sides among the two pairs of sides may be longer than the other pair of sides.

At least a portion of the display panel DP may have flexibility, and may be folded at the portion having the flexibility. However, embodiments are not limited thereto.

The display panel DP may display an image. A self-luminescent display panel or a non-self-luminescent display panel may be used as the display panel DP.

The display panel DP may include a substrate SUB and pixels PXL disposed on the substrate SUB.

The substrate SUB may include a transparent insulating material such that light may be transmitted therethrough, but embodiments are not limited thereto. The substrate SUB may be a rigid substrate or a flexible substrate.

The rigid substrate may be one of a glass substrate, a quartz substrate, a glass ceramic substrate, and a crystalline glass substrate.

The flexible substrate may be one of a film substrate and a plastic substrate, which include a polymer organic material. For example, the flexible substrate may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate.

An area of the substrate SUB may be provided as the display area DA such that the pixels PXL are disposed therein, and another area on the substrate SUB may be provided as a non-display area NDA. For example, the substrate SUB may include the display area DA including pixel areas PXA in which the respective pixels PXL are disposed and the non-display area NDA disposed at the periphery of the display area DA (or adjacent to the display area DA).

The non-display area NDA may be adjacent to the display area DA. The non-display area NDA may be disposed at least one side of the display area DA. For example, the non-display area NDA may surround a circumference (or edge portion) of the display area DA. A line part connected to each pixel PXL and a driver, which is connected to the line part and drives the pixel PXL, may be formed in the non-display area NDA.

Each of the pixels PXL may be provided in plurality to be arranged in a matrix form along rows extending in a first direction DR1 and columns extending in a second direction DR2 intersecting the first direction DR1. However, the arrangement form of the pixels PXL is not limited, and the pixels PXL may be arranged in various forms. In some embodiments, in case that each of the pixels is provided in plurality, the pixels PXL may be provided to different areas (or sizes). For example, in case that pixels PXL have different colors of lights emitted therefrom, the pixels PXL may be provided to have different areas (or sizes) or different shapes with respect to the different colors.

The driver may provide a certain signal and a certain voltage to each pixel PXL through the line part, thereby controlling driving of the pixel PXL.

The display panel DP (or each of the pixels PXL) may include a pixel circuit layer PCL, a display element layer DPL, and an encapsulation layer TFE, which are positioned on the substrate SUB.

The pixel circuit layer PCL may be disposed on the substrate SUB, and include a transistor and signal lines connected to the transistor. For example, the transistor may have a form in which an active pattern layer (or semiconductor pattern layer), a gate electrode, a source electrode, and a drain electrode are sequentially stacked with an insulating layer interposed therebetween. The semiconductor pattern layer may include amorphous silicon, poly-silicon, low temperature poly-silicon, an organic semiconductor, and/or an oxide semiconductor. The gate electrode, the source electrode, and the drain electrode may include at least one of aluminum (Al), copper (Cu), titanium (Ti), and molybdenum (Mo), but embodiments are not limited thereto. For example, the pixel circuit layer PCL may include at least one insulating layer.

The display element layer DPL may be disposed on the pixel circuit layer PCL. The display element layer DPL may include a light emitting element emitting light. The light emitting element may be, for example, an organic light emitting diode.

The encapsulation layer TFE may be selectively disposed on the display element layer DPL. The encapsulation layer TFE may be an encapsulation substrate or have the form of an encapsulation film formed as a multi-layer. In case that the encapsulation layer TFE has the form of the encapsulation film, the encapsulation layer TFE may include an inorganic layer and/or an organic layer. For example, the encapsulation layer TFE may have a form in which an inorganic layer, an organic layer, and an inorganic layer are sequentially stacked. The encapsulation layer TFE may prevent external air and moisture from infiltrating (or permeating) into the display element layer DPL and the pixel circuit layer PCL.

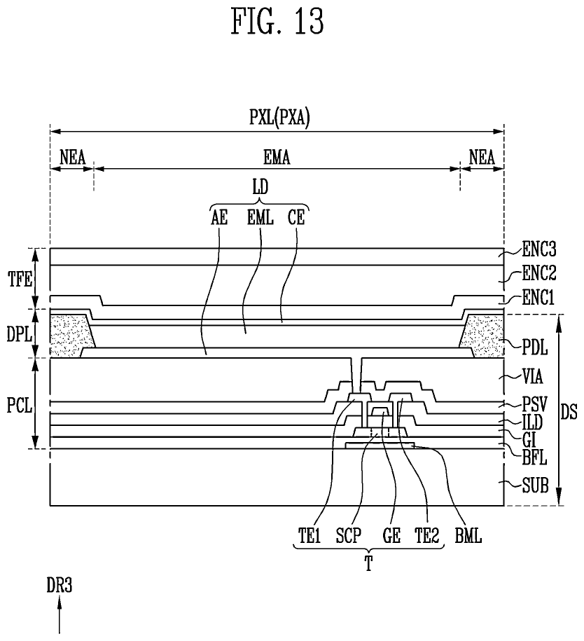

FIG. 13 is a schematic sectional view illustrating the pixel PXL shown in FIG. 11.

In FIG. 13, portions different from those of the above-described embodiment will be described to avoid redundancy.

Referring to FIGS. 11, 12, and 13, the pixel PXL may be positioned in a pixel area PXA of the display area DA. The pixel area PXA may include an emission area EMA and a non-emission area NEA.

The pixel PXL (or the display panel DP) may include a substrate SUB, a pixel circuit layer PCL, a display element layer DPL, and an encapsulation layer TFE.

The pixel circuit layer PCL and the display element layer DPL may be disposed on a surface of the substrate SUB to overlap each other. For example, the pixel area PXA of the substrate SUB may include the pixel circuit layer PCL disposed on the surface of the substrate SUB and the display element layer DPL disposed on the pixel circuit layer PCL. However, the mutual positions of the pixel circuit layer PCL and the display element layer DPL on the substrate SUB may vary in some embodiments.

The substrate SUB may include a transparent insulating material such that light may be transmitted therethrough. The substrate SUB may be a rigid substrate or a flexible substrate.

Circuit elements (e.g., a transistor T) which are disposed on the substrate SUB and are electrically connected to a light emitting element LD may be disposed in the pixel circuit layer PCL. At least one insulating layer may be disposed in the pixel circuit layer PCL. The insulating layer may include a buffer layer BFL, a gate insulating layer GI, an interlayer insulating layer ILD, a passivation layer PSV, and a via layer VIA, which are sequentially stacked on the substrate SUB along the third direction DR3.

The buffer layer BFL may be disposed (e.g., entirely disposed) on the substrate SUB. The buffer layer BFL may prevent an impurity from being diffused (or permeated) into the transistor T. The buffer layer BFL may be an inorganic insulating layer including an inorganic material. For example, the buffer layer BFL may include at least one of silicon nitride (SiNₓ), silicon oxide (SiOₓ), and silicon oxynitride (SiOₓN_{y}), or include at least one of metal oxides such as aluminum oxide (AlOₓ). The buffer layer BFL may be formed as a single layer. In another example, the buffer layer BFL may be formed as a multi-layer including at least two layers. In case that the buffer layer BFL is provided as the multi-layer, the layers may be formed of the same material or be formed of different materials. The buffer layer BFL may be omitted according to a material of the substrate SUB, a process condition, and the like.

The transistor T may be disposed on the buffer layer BFL. The transistor T may include a semiconductor pattern layer SCP, a gate electrode GE, a first terminal TE1, and a second terminal TE2.

The semiconductor pattern layer SCP may be a semiconductor pattern layer, which is made of poly-silicon, amorphous silicon, an oxide semiconductor, or the like. The semiconductor pattern layer SCP may include a first contact region (or source region) in contact with the first terminal TE1 and a second contact region (or drain region) in contact with the second terminal TE2. For example, the semiconductor pattern layer SCP may include a channel region which is positioned between the first contact region and the second contact region and overlaps the gate electrode GE. The channel region may be an intrinsic semiconductor pattern layer, which is not doped with an impurity, and each of the first contact region and the second contact region may be a semiconductor pattern layer, which is doped with the impurity.

The gate insulating layer GI may be provided and/or formed (e.g., entirely provided and/or formed) on the semiconductor pattern layer SCP and the buffer layer BFL.

The gate electrode GE may be disposed on the channel region of the semiconductor pattern layer SCP with the gate insulating layer GI interposed therebetween. The gate electrode GE may include a low resistance material. For example, the gate electrode GE may include a conductive material including molybdenum, aluminum, copper, titanium, and the like, and may be formed as a multi-layer or a single layer, which includes the above-described materials.

The gate insulating layer GI positioned between the semiconductor pattern layer SCP and the gate electrode GE may include the same material as the above-described buffer layer BFL, or include a (or selected) material among the materials such as the material of the buffer layer BFL. For example, the gate insulating layer GI may be an inorganic insulting layer including an inorganic material. In some embodiments, the gate insulating layer GI may be etched together with a base conductive material of the gate electrode GE in a manufacturing process of the gate electrode GE to be disposed on only the bottom of the gate electrode GE. The gate insulating layer GI may have the same width as the gate electrode GE positioned on the top thereof, but embodiments are not limited thereto.

The interlayer insulating layer ILD may be disposed on the gate electrode GE and the gate insulating layer GI.

The interlayer insulating layer ILD may include the same material as the above-described buffer layer BFL, or include a (or selected) material among the materials such as the material of the buffer layer BFL. For example, the interlayer insulating layer ILD may be an inorganic insulting layer including an inorganic material.

The first terminal TE1 and the second terminal TE2 may be provided and/or formed on the interlayer insulating layer ILD. The first terminal TE1 (or source electrode) may be in contact with the first contact region of the semiconductor pattern layers SCP through a contact hole sequentially penetrating the interlayer insulating layer ILD and the gate insulating layer GI. The second terminal TE2 (or drain electrode) may be in contact with the second contact region of the semiconductor pattern layer SCP through a contact hole sequentially penetrating the interlayer insulating layer ILD and the gate insulating layer GI. The first terminal TE1 and the second terminal TE2 may include a material having excellent conductivity. For example, the first terminal TE1 and the second terminal TE2 may include a conductive material including molybdenum, aluminum, copper, titanium, and the like, and may be formed as a multi-layer or a single layer, which includes the above-described materials.

A bottom metal pattern layer BML may be disposed under the transistor T. The bottom metal pattern layer BML may be a conductive layer disposed between the substrate SUB and the buffer layer BFL, and may include the same material as the gate electrode GE, or include a (or selected) material among the materials such as the material of the gate electrode GE. The bottom metal pattern layer BML may include a material among the materials such as the material of the first and second terminals TE1 and TE2. The bottom metal pattern layer BML may overlap the transistor T. In some embodiments, the bottom metal pattern layer BML may be electrically connected to the transistor T, to stabilize the channel region of the transistor T.

The passivation layer PSV may be provided and/or formed on the transistor T and the interlayer insulating layer ILD. A portion of the passivation layer PSV may be removed to expose a portion of the first terminal TE1. The passivation layer PSV may include the same material as the buffer layer BFL, or include a (or selected) material among the materials such as the material of the buffer layer BFL.

The via layer VIA may be provided and/or formed on the passivation layer PSV. The via layer VIA may be an inorganic insulating layer including an inorganic material or an organic insulating layer including an organic material. The inorganic insulating layer may include, for example, at least one of silicon oxide (SiOₓ), silicon nitride (SiNₓ), silicon oxynitride (SiOₓN_{y}), and aluminum oxide (AlOₓ). The organic insulating layer may include, for example, at least one of acrylic resin, epoxy resin, phenolic resin, polyamide resin, polyimide resin, unsaturated polyester resin, poly-phenylene ether resin, poly-phenylene sulfide resin, and benzocyclobutene resin. In an embodiment, the via layer VIA may be an organic insulating layer including an organic material (or substance). The via layer VIA may be partially opened to expose the first terminal TE1 exposed by the passivation layer PSV.

The display element layer DPL may be provided and/or formed on the via layer VIA.

The display element layer DPL may include the light emitting element LD and a pixel defining layer PDL. The light emitting element LD may include a first electrode AE, a light emitting layer EML, and a second electrode CE. For example, the light emitting element LD may further include a common layer disposed between the first electrode AE and the light emitting layer EML or between the light emitting layer EML and the second electrode CE.

In an embodiment, the substrate SUB, the pixel circuit layer PCL, the pixel defining layer PDL, and the first electrode AE may be included in the target substrate DS described with reference to FIGS. 1 to 5.

The first electrode AE (or pixel electrode) may be provided and/or formed on the via layer VIA. The first electrode AE may be an anode of the light emitting element LD. The first electrode AE may be connected (e.g., electrically connected) to the first terminal TE1 of the transistor T. The first electrode AE may include a conductive material (or substance). The conductive material may include an opaque metal. The opaque metal may include, for example, metals such as silver (Ag), magnesium (Mg), aluminum (Al), platinum (Pt), palladium (Pd), gold (Au), nickel (Ni), neodymium (Nd), iridium (Ir), chromium (Cr), titanium (Ti), and alloys thereof. However, the material of the first electrode AE is not limited to the above-described embodiment. In some embodiments, the first electrode AE may include a transparent conductive material (or substance). The transparent conductive material (or substance) may include a conductive oxide such as indium tin oxide (ITO), indium zinc oxide (IZO), zinc oxide (ZnO), indium gallium zinc oxide (IGZO), or indium tin zinc oxide (ITZO), a conductive polymer such as poly(3,4-ethylenedioxythiophene (PEDOT), and the like. In case that the first electrode AE includes the transparent conductive material (or substance), a separate conductive layer may be added, which is made of an opaque metal for reflecting light emitted from the light emitting layer EML in an image display direction of the display device DD (or an upper direction of the encapsulation layer TFE).

The pixel defining layer PDL may be provided and/or formed over the first electrode AE. The pixel defining layer PDL may include an opening exposing an area of the first electrode AE, and cover an edge portion of the first electrode AE. The pixel defining layer PDL may define the emission area EMA of the pixel PXL. The pixel defining layer PDL may include an organic insulating layer made of an organic material. The organic material may include acrylic resin, epoxy resin, phenolic resin, polyamide resin, polyimide resin, and the like. In some embodiments, the pixel defining layer PDL may include a light absorption material or have a light absorber coated thereon, to absorb light introduced (or incident) from the outside. For example, the pixel defining layer PDL may include a carbon-based black pigment. However, embodiments are not limited thereto.

The light emitting layer EML may be disposed on the top of the area of the first electrode AE, which is exposed by the opening of the pixel defining layer PDL. The light emitting layer EML may include a light generation layer which generates certain light and includes a high molecular organic material or a low molecular organic material. The light emitting layer EML may be formed of at least one material among materials emitting lights of red, green, and blue, and include a fluorescent material or a phosphorescent material. The light emitting element EML may emit light in response to a potential difference between the first electrode AE and the second electrode CE.

For example, the light emitting layer EML may further include a common layer in addition to the light generation layer. The common layer may include at least one of a hole injection layer, a hole transport layer, an electron transport layer, and an electron injection layer.

The apparatus 1 shown in FIGS. 1 to 5 may form various layers on the target substrate DS. The apparatus 1 may form at least one layer among the layers included the light emitting layer EML on the target substrate DS. For example, the apparatus 1 may form at least one of hole injection layer, the hole transport layer, the electron transport layer, and the electron injection layer.

The second electrode CE may be provided and/or formed on the light emitting layer EML.

The second electrode CE (or common electrode) may be commonly provided and/or formed in the pixels PXL. The second electrode CE may be provided and or formed in a plate shape throughout the whole of the display area DA, but embodiments are not limited thereto. The second electrode CE may be a thin metal layer having a thickness such that light emitted from the light emitting layer EML may be transmitted therethrough. The second electrode CE may be formed of a metal material or be formed of a transparent conductive material to have a relatively thin thickness. For example, the second electrode CE may include at least one of various transparent conductive materials including indium tin oxide, indium zinc oxide, indium tin zinc oxide, aluminum zinc oxide, gallium zinc oxide, zinc tin oxide, and gallium tin oxide, and may be formed substantially transparent or translucent to satisfy a predetermined transmittance. Accordingly, light emitted from the light emitting layer EML positioned on the bottom of the second electrode CE may be emitted upwardly from the encapsulation layer TFE by passing through the second electrode CE.

The encapsulation layer TFE may include a first encapsulation layer ENC1, a second encapsulation layer ENC2, and a third encapsulation layer ENC3, which are sequentially stacked over the second electrode CE. The first encapsulation layer ENC1 may be formed on the display element layer DPL (or the second electrode CE), and may be positioned throughout the display area DA and at least a portion of the non-display area NDA. The second encapsulation layer ENC2 may be formed on the first encapsulation layer ENC1, and may be positioned throughout the display area DA and at least a portion of the non-display area NDA. The third encapsulation layer ENC3 may be formed on the second encapsulation layer ENC2, and may be positioned throughout the display area DA and at least a portion of the non-display area NDA. In some embodiments, the third encapsulation layer ENC3 may be positioned throughout the entire display area DA and the non-display area NDA.

Each of the first and third encapsulation layers ENC1 and ENC3 may be formed as an inorganic layer including an inorganic material, and the second encapsulation layer ENC2 may be formed as an organic layer including an organic material. The inorganic layer may include, for example, silicon nitride (SiNₓ), silicon oxide (SiOₓ), silicon oxynitride (SiOₓN_{y}), or the like. The organic layer may include an organic insulating material such as acrylic resin, epoxy resin, phenolic resin, polyamides resin, polyimides resin, polyester resin, poly-phenylene sulfide resin, or benzocyclobutene (BCB).

In accordance with the disclosure, a deposition material (or deposition substance) sprayed from a nozzle may be prevented from being deposited on an angle control member, thereby reducing loss of the deposition material, so that deposition efficiency may be improved.

In accordance with the disclosure, a mirror-finished heat dissipation member may be disposed at an outside of the angle control member, thereby reducing or minimizing the transfer of the heat generated in a deposition source and the angle control member to a substrate and a mask. Thus, deformation of the substrate and the mask may be reduced.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. An apparatus for manufacturing a display device, the apparatus comprising:
a substrate;
a nozzle including a nozzle hole that sprays a deposition material on the substrate;
a crucible connected to the nozzle, the crucible storing the deposition material;
a reflector disposed on the crucible, the reflector including an opening area overlapping the nozzle; and
an angle control member connected to the reflector, wherein
the angle control member includes:
a first member disposed to face the nozzle,
a third member disposed to face the substrate, and
a second member disposed between the first member and the third member.

2. The apparatus of claim 1, wherein the second member includes a heater that includes a heat wire and applies heat to the first member.

3. The apparatus of claim 2, wherein the first member includes a heat dissipation member having a high emissivity.

4. The apparatus of claim 2, wherein the third member includes a plurality of heat dissipation members each having a low emissivity.

5. The apparatus of claim 4, wherein each of the plurality of heat dissipation members is mirror-finished to reflect radiant heat transmitted from the heater.

6. The apparatus of claim 1, wherein the angle control member has an inclination angle of about 40° to about 70°.

7. The apparatus of claim 6, wherein the angle control member includes a first angle control member and a second angle control member, which are spaced apart from each other.

8. The apparatus of claim 7, wherein
the first angle control member has a first inclination angle of about 40° to about 70°, and
the second angle control member has a second inclination angle of about 40° to about 70°.

9. The apparatus of claim 8, wherein the first inclination angle and the second inclination angle are same as each other.

10. The apparatus of claim 8, wherein the first inclination angle and the second inclination angle are different from each other.

11. The apparatus of claim 7, wherein
each of the first and second angle control members includes:
a first part connected to the reflector, and
a second part extending from the first part toward the substrate, and
the second part has an inclination angle of about 40° to about 70°.

12. The apparatus of claim 7, wherein each of the first and second angle control members includes a curve having a curvature.

13. The apparatus of claim 12, wherein an angle formed by a tangent line in contact with an arbitrary point of the curve and a virtual line parallel to a main surface of the reflector is in a range of about 40° to about 70°.

14. The apparatus of claim 7, wherein
each of the first and second angle control members includes:
a first part connected to the reflector, and
a second part extending from the first part toward the nozzle, and
an angle formed by the first part and the second part is in a range of about 40° to about 70°.

15. The apparatus of claim 1, further comprising:
a heater heating the crucible and disposed at an outer periphery of the crucible.

16. An apparatus for manufacturing a display device, the apparatus comprising:
a crucible including an accommodation part storing a deposition material to be deposited on a substrate;
a heater disposed at an outside of the crucible, the heater that heats the crucible and evaporates the deposition material;
a nozzle communicating with the accommodation part, the nozzle including a nozzle hole that sprays the deposition material toward the substrate;
a reflector disposed between the crucible and the nozzle, the reflector that blocks heat exchange between the crucible and the nozzle; and
an angle control member connected to the reflector, wherein
the angle control member includes a first member, a second member, and a third member, and
the second member includes a heat wire and applies heat to the first member.

17. The apparatus of claim 16, wherein the angle control member has an inclination angle of about 40° to about 70°.

18. The apparatus of claim 16, wherein
the first member is disposed to face the nozzle,
the third member is disposed to face the substrate, and
the second member is disposed between the first member and the third member.

19. The apparatus of claim 18, wherein
the first member includes a heat dissipation member having a high emissivity, and
the third member includes a plurality of heat dissipation members each having a low emissivity.

20. The apparatus of claim 19, wherein each of the plurality of heat dissipation members is mirror-finished to reflect heat transmitted from the second member.
